(19) United States
(12) Patent Application Publication
(10) Pub. No.: US 2010/0207630 A1
(43) Pub. Date: Aug. 19, 2010

(54) PASSIVE SHIMMING OF MAGNET SYSTEMS

(76) Inventors: Timothy Barnes, Oxford (GB); Benjamin John Catmull, London (GB); John Hedley Toyer, Eynsham (GB); Ian Wilkinson, Long Hanborough (GB)

Correspondence Address: SCHIFF HARDIN, LLP;PATENT DEPARTMENT, 233 S. Wacker Drive-Suite 6600, CHICAGO, IL, 60606-6473, US

(21) Appl. No.: 12/767,270

(22) Filed: Apr. 26, 2010

Related U.S. Application Data
(63) Continuation of application No. 12/301,139, filed on Nov. 17, 2008, now abandoned.

(30) Foreign Application Priority Data
Jul. 6, 2006 (GB) 0613389.6

(51) Int. Cl. G01R 33/48

(52) U.S. Cl. 324/314

(57) ABSTRACT

In a method and an arrangement for shimming a cylindrical magnet system, that has a cylindrical magnet having a bore therein with an axis extending therethrough, and a gradient coil assembly located within the bore, shimming is accomplished by stacking a number of planar pieces of shim material in each of said tubes, with each of the tubes having an axis parallel to the axis of the cylindrical magnet, and with the planar pieces of shim material and stacked in the tubes in respective planes that are perpendicular to the axis of the cylindrical magnet.

### RELATED APPLICATION

The present application is a continuation of Ser. No. 12/301,139, filed on Nov. 17, 2008 (now abandoned).

### BACKGROUND OF THE INVENTION

1. Field of the Invention

The present invention relates to shimming of magnet systems, and in particular to passive shimming of magnet systems.

2. Description of the Prior Art

Applications such as magnetic resonance imaging (MRI) or nuclear magnetic resonance (NMR) imaging require magnetic fields of high strength and very high homogeneity. Such magnetic fields are commonly provided by electromagnets comprising a number of superconducting or resistive coils arranged in a fixed arrangement.

As is well known in the art, considerable effort goes into the design of magnet systems to enable them to produce high strength homogeneous fields. However, it is not possible to design a magnet which will produce its designed homogeneity in a real application. Manufacturing tolerances inevitably displace the coils from their design position, and characteristics of the wire used may be different from those assumed in the design process. Furthermore, when a magnet is installed at an operational site, the magnetic field it can produce will be influenced by the surroundings. For example, in a hospital setting, the structure of the building will typically contain structural steel, and other pieces of equipment nearby will influence the final field produced by the magnet system. For these reasons, shimming is used to correct for deviations of the actual field away from the design field, to improve that actual field so as to more closely approximate to the designed field. Two types of shimming are known: active shimming involves the control of electric current through shim coils added into the magnet system for the purpose. Current through each coil is adjusted so that it produces a magnetic field which influences the field of the magnet system as a whole. Passive shimming, on the other hand, involves the placement of pieces of magnetic material, typically steel, within the magnetic field to deform the actual magnetic field such that it more closely resembles the designed magnetic field.

The present invention addresses passive shimming arrangements in magnet systems for imaging.

In magnet systems for imaging, a number of coils carry an electric current to generate a high strength, relatively homogeneous magnetic field. This field may be referred to as the main or basic field, or the background field. In addition, a gradient field is required. Rather than being homogeneous, the gradient field varies in intensity along an axis of the main field. In hollow cylindrical magnet systems, the coils generating the main field are axially aligned. Typically, gradient coils are arranged in a tubular space radially inside of the main field coils. In typical arrangements, the gradient coils are formed by resistive wire embedded in a potting material such as a resin.

Known passive shimming arrangements employ shim trays, typically long cuboid trays of rectangular cross section which, in use, are housed within slots formed in the potting material of the gradient coils, in directions parallel to the magnet axis. The shim trays include a number of pockets along their length. Shim pieces, typically flat square or rectangular pieces of steel, are placed within the pockets, and the shim tray is then introduced into the gradient coils. By providing a number of shim trays arranged around the gradient coils, many shim pockets are provided in a variety of radial and circumferential positions. For example, 12 trays may be employed, each having 15 pockets, giving a total of 180 shim pockets. Each shim pocket may contain a number of shim pieces; each shim piece may have one of a variety of thicknesses. Computer simulation is typically used to calculate the number of shim pieces which should be placed in each shim pocket. The quantity of shim material in each pocket may be adjusted by adding an appropriate quantity of identical shim pieces, or shim pieces of differing thicknesses may be used.

Present shimming calculation techniques involve arranging square shims in an array of pockets arranged through the bore of the magnet. Shims are stacked so for any given shim pocket, the stack height is radial to the magnetic field, while the grain orientation (easy magnetization axis) of the shim is aligned with the axial magnetic field. In practice this leads to an approximately linear relationship between the thickness of the shims in a pocket, and the effect on the volume of the magnet system. This allows for the use of numerical optimization techniques to solve for a measured set of magnetic field contaminants.

Current arrangements typically use square or rectangular plates of grain-orientated silicon-iron as the shim material. These plates have an easy magnetization axis which is arranged parallel to the main magnet axis, and they are stacked in a radial direction in the pockets. Because of the direct relationship between shim mass and both B₀ drift—and thus image quality—and installation time, a shimming scheme which reduces the amount of shim mass used would be advantageous in reducing the size of the shimming arrangement, reducing B₀ drift and also in improving the accuracy and time taken to load the shim material in the magnet.

US patent application 2003/0206018 describes arrangements for positioning of shim material in magnetic resonance apparatus, and carrier device, such as a shim tray, which may be equipped with shim elements. FIG. 5 shows an example of shim pieces 160 placed in rectangular section slots 120 in gradient coils 110, as described in the cited US patent application.

### SUMMARY OF THE INVENTION

The present invention addresses several technical problems with such conventional arrangements for passive shimming of magnet systems, such as superconducting electromagnets or permanent magnets for nuclear magnetic resonance or magnetic resonance imaging systems.

In particular, the present invention addresses one or more of the following problems.

The existing shim trays result in a low volume fraction of shimming material in the space set aside in the gradient coil for shimming. This is partly due to the need to provide sufficient space in all pockets for a certain maximum number of shims, and partly due to the need to accommodate the shim tray itself. It has been estimated that in a typically shimmed magnet system, only about 35% of the volume set aside for shimming is in fact occupied by shimming material. The remaining 65% is in effect wasted space. Since designers of such magnet systems seek to optimize use of space, in order to shorten or widen the bore of a hollow cylindrical magnet, such waste of space is desired to be avoided. To minimize the wasted space, the capacity of each pocket of the shim tray may be limited. However, this in turn not only limits the volume of shim material which can be loaded, but also means that the shim pockets near the most sensitive regions, typically towards the centre of the magnet, are filled up quickly, forcing any further required shim material into less sensitive regions and consequently increasing the mass of shim material required to achieve the desired shimming effect.

The existing shim trays, and the corresponding slots in the gradient coils, are rectangular in cross-section. This leads to stress concentration at the corners of the slots, which tends to impair the structural integrity of the gradient coil.

Shim material placed within the slots in the gradient coils tends to heat up when the magnet is energized. This variation in temperature leads to variations in the magnetic properties of the shim material. While the shim material may be effective to provide a certain level of magnetic field homogeneity at a certain temperature, variation in the temperature of the shim material will cause variation in the homogeneity of the resultant magnetic field. Such effect is well known, and is commonly referred to as B₀ drift.

The provision of shims in known arrangements typically involves the manual placement of shim pieces in the appropriate pockets of each shim tray, and the manual placement and extraction of the shim trays when the magnet is inoperative. This process is time-consuming, manually intensive and prone to errors. The process has been found difficult to automate.

Existing shimming software, that is, the software which calculates the quantity and position in which shim material is to be placed, assumes that the direction in which the shim material such as iron is magnetized is parallel to that of the main field; no allowance is made for any radial components of the magnetization vector, although such radial components may in fact exist in the shim material used.

The above problems are avoided, or at least significantly alleviated, in a cylindrical magnet system for magnetic resonance imaging constructed in accordance with the present invention, wherein the cylindrical magnet system includes a cylindrical magnet having a bore therein and a gradient coil assembly located within the bore, and wherein the magnetic system further includes an arrangement for passive shimming of the cylindrical magnet, formed by tubes that are a part of the gradient coil assembly, the tubes being oriented in a direction parallel to the axis of the cylindrical magnetic in order to accommodate planar pieces of shim material, with the planar pieces of shim material being stacked into the tubes so as to lie respectively in planes perpendicular to the axis of the cylindrical magnet.

The above objects also are achieved in accordance with the present invention by a method for shimming a magnet system that includes the steps of stacking planar pieces of shim material in tubes of a gradient coil assembly associated with a cylindrical magnet to be shimmed, the planar pieces of shim material being stacked into the tubes so as to respectively lie in planes perpendicular to the axis of the cylindrical magnet.

### BRIEF DESCRIPTION OF THE DRAWINGS

FIG. 1 illustrates a detail of shim pieces mounted on a carrier in accordance with a feature of an embodiment of the present invention.

FIG. 2 illustrates an arrangement of tubes in a gradient coil assembly, arranged to accommodate shim material according to a feature of an embodiment of the present invention.

FIGS. 3A-3B illustrate aspects of a method for simulating radial and axial magnetic effects of the shim material.

FIG. 4 illustrates an overview of a shim optimization method provided by the present invention.

FIG. 5 illustrates a cross-section of a shim arrangement of the prior art.

### DESCRIPTION OF THE PREFERRED EMBODIMENTS

According to an aspect of the present invention, shim trays are dispensed with. Furthermore, substantially planar shim pieces are arranged perpendicular to the axis of a hollow cylindrical magnet. Preferably, the shim pieces are planar, and more preferably circular, and the gradient coil assembly is provided with a number of cylindrical shim tubes for accommodating the shim pieces. Preferably, an arrangement is provided for cooling the shim pieces in-situ.

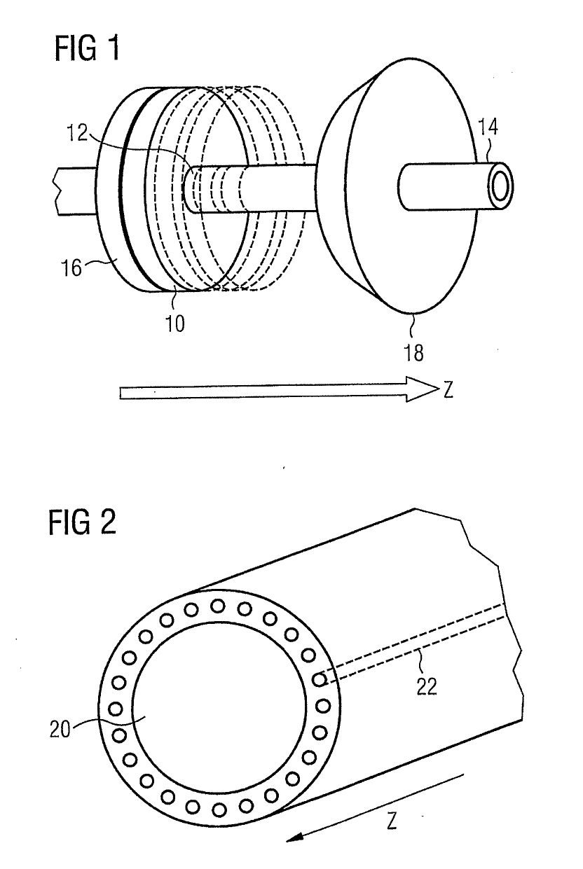

The geometry of certain embodiments of the present invention, given by way of example only, is shown schematically in FIGS. 1 and 2.

FIG. 1 shows a detail of a shim arrangement according to an aspect of the present invention. According to this embodiment of the invention, discs 10 of shimming material are arranged within the gradient coil assembly 20 (FIG. 2) in tubes 22 of complementary cross-section, provided for the purpose. In the illustrated embodiment, the discs 10 are circular, and the tubes 22 have a circular cross section. In alternative embodiments, the discs 10 may be elliptical, and the tubes 22 may have an elliptical cross-section. In such embodiments, it is possible to arrange the shim pieces to have a determined orientation with respect to the gradient coil assembly as a whole, which would be difficult to arrange with circular discs 10. In further alternative arrangements, the discs 10 may be triangular, square, rectangular, hexagonal or virtually any planar shape. Embodiments may even provide substantially planar shim pieces which nevertheless have complementary upper and lower surface features, which can be closely stacked within the tubes 22. Such arrangements may allow the shim pieces to have a determined orientation with respect to each other.

According to a feature of the illustrated embodiment, the discs 10 of shimming material are provided with through-holes 12. In use, the discs 10 are mounted on a carrying rod 14 by passing the rod 14 through the through-hole 12 in each disc 10.

Similarly to the known shimming methods, a computerized optimization program is used to calculate the required positioning of the discs 10 of shimming material 10 within each tube 22. Non-magnetic spacing discs 16 are used in positions where no shimming disc 10 is required, in order to ensure correct positioning and retention of the discs 10 of shimming material in their intended positions. Once the computer program has calculated the required shim positions for each tube 22, discs 10 of shimming material and non-magnetic spacing discs 16 are loaded onto corresponding carrying rods 14 in the respective correct order. The carrying rods with discs of shimming material and non-magnetic spacing discs are each then loaded into their respective tube 22. Preferably, an end support plug 18 is provided at the or each open end of each tube 22 to prevent movement of the carrying rods with discs of shimming material and non-magnetic spacing discs. Each end support plug 18 may be provided with a through-hole, through which carrying rod 14 may pass. Alternatively, the end support plugs may not be provided with a through-hole, and each carrying rod 14 may be wholly retained within its tube 22.

The non-magnetic spacing discs both support the discs of shimming material, and allow the build up of a distribution of shimming material that will substantially improve the homogeneity of the main magnetic field. Tapered plugs at each end of the support rod hold the rod (and shims) securely in the gradient coil. The axes of the shim tubes in the gradient coil, and of the discs within the tubes, are coincident and parallel to the main magnet (z-) axis.

In preferred embodiments of the present invention, carrying rod 14 may be provided as a hollow tube, through which a cooling fluid, such as water, may be arranged to pass. In such arrangements, shim pieces 10 are held at a relatively constant temperature, and variation of the shimming effect, causing B₀ drift, due to temperature variation of the shims, will be reduced.

In a preferred embodiment, a variety of shim pieces 10 are used, having varying axial extents, which may be regarded as a thickness of each shim piece. The varying axial extents mean that certain shim pieces contain more shim material than others, and so have differing shimming effects. In such an embodiment, all shims preferably have a same size and shape in a radial plane, said size and shape being such as to substantially correspond to the cross-section of the respective tube 22. In alternative embodiments, shim pieces 10 of varying sizes and/or shapes may be used. The varying sizes and/or shapes mean that certain shim pieces contain more shim material than others, and so have differing shimming effects. The varying sizes and/or shapes may be used in conjunction with varying axial extent (thickness) to provide a wide range of shims of differing shimming effects.

The shim pieces and the cross-section of each shim tube are preferably rounded, and more preferably circular. Rounded, rather than rectangular, cross-section tubes through the gradient coil 20 enable a stiffer gradient coil structure for the same gradient coil volume set aside for shimming, as the stress concentration formerly observed at corners of shim tray slots is avoided. Discs 10 of shimming material mounted on a central support rod 14 or pipe, according to the present invention, give a much greater filling factor with shim material in the tubes 22 than do plates loaded into pockets in a shim tray of the prior art. Greater filling factor means more shim material can be placed in the most sensitive regions, reducing overall shim mass. The provision of a cooling pipe in good thermal contact with the shim material alleviates the image quality issues associated with temperature variation of the shims.

Finally, the process of loading discs onto a rod or threaded bar or pipe is much easier to automate than the current process of loading plates into pockets in trays. Automatic loading of shim material would be both quicker and more accurate than in known methods, not only speeding up a shimming iteration but may also reduce the number of iterations required.

Although the present invention accordingly alleviates at least some of the difficulties of the prior art, new difficulties have been found to arise. Discs of shimming material of different axial extent are found to have non-linear effects. Present techniques rely on changing the aspect of the shim in the radial direction, which is believed to have a more linear effect.

The presence of significant radial component of the magnetization vector in the shim material introduces a further difficulty in shimming optimization calculations. Present techniques rely on the grain orientation of the shim material to force the magnetic field into the axial direction over the shim. The shim pieces of the present invention are arranged in radial planes, which have radial effects.

The greatly increased number of shim discs which could make up a shim distribution in the new geometry, complicates the optimization process as compared to the number of plates used in a comparable shim distribution in existing shimming geometries.

With shims arranged in radial planes, consideration has to be given to non-axial magnetization effects introduced by the material of the shims. The magnetic field may be sensitive to distortion due to the shim material in both radial (r) and axial (z) directions—which may be referred to as Mr/Mz sensitivity.

The present invention also provides methods useful in calculating the required quantity and position of shim material. These methods include the following elements.

### Shim Sensitivity

Formulae may be derived for shims of constant cross-section and varying in Z, taking into account change in Mr (radial magnetization) and Mz (axial magnetization) over the shim cross section, where “radial” and “axial” refer to directions respectively perpendicular, and parallel, to the main axis Z of the magnet system. This becomes the basis for an optimization scheme to minimize inhomogeneity (or Maximize

Homogeneity) over the target field of view of an imaging system.

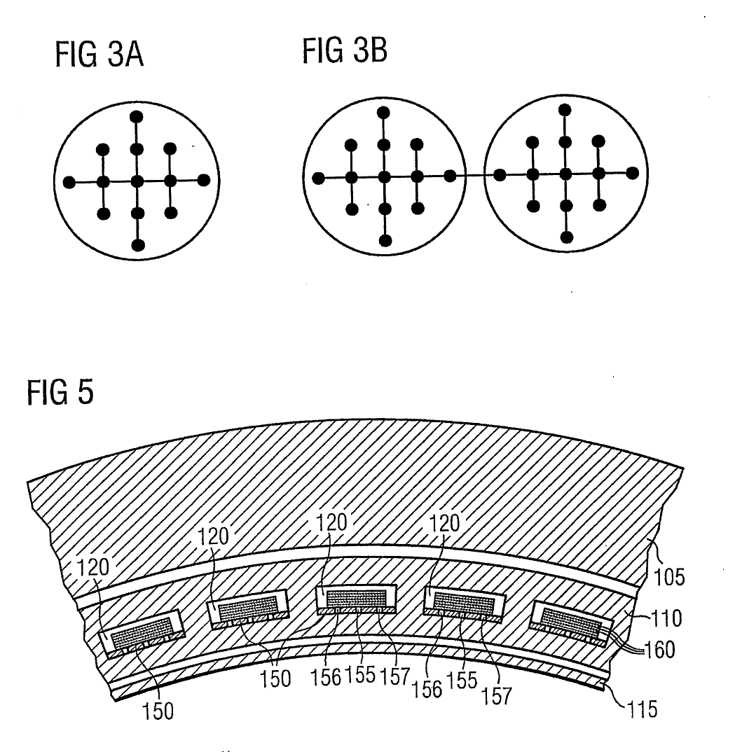

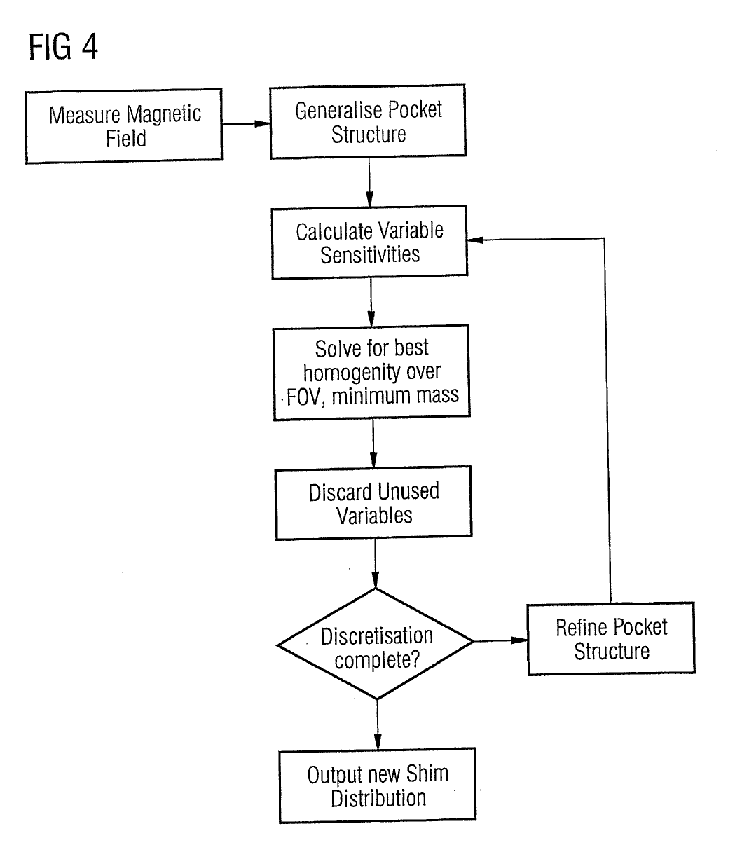

FIGS. 3A-3B illustrate aspects of a method for simulating radial and axial magnetic effects of the shim material on the resultant magnetic field. The magnetization vector, which describes the direction of the magnetic field at a point, will change radially, so the magnetization vector needs to be evaluated across the surface of the shim disc, which, according to the present invention, is located in a radial plane.

FIG. 3A shows an example of selected points on a shim disc, which may be used in the evaluation of Mr/Mz sensitivity in a shim arrangement of the present invention. As the shim discs are stacked within each shim tube, each point in FIG. 3A represents a one-dimensional filament extending the length of the shim in tube 22. At each point, a point sensitivity may be calculated, and this may be calculated the length of the filament. In order to reduce the number of calculations required, accurate calculation of point sensitivities is only performed in locations where shims are likely to be required. Such locations may be calculated in a first-pass shimming optimization calculation. Resultant calculated point sensitivities may be supplied back to the optimizer in order to calculate an optimized shim distribution.

In known shim arrangements, such as shown in FIG. 5, the number of shim slots may be approximately sixteen. In an embodiment of the present invention, about seventy shim tubes 22 may be employed. Due to the very significant increase in the possible locations for shim discs, due to the increased number of tubes of the present invention as compared to slots of the prior art, and the increased number of shim pieces which could be accommodated in each tube, the total number of calculations required to produce an optimized shim distribution may become very large.

Iterating the Solutions

In an example embodiment of the present invention, approximately 70 2.5 cm diameter tubes (see FIG. 2) are required. Dividing these tubes into zones of similar axial length to conventional shim tray gives a total number of optimization variables of 1050 (70×15), against a more conventional 240 variables. This level of discretization presents a difficult problem for the optimizer, as the data sets are relatively large while the effect of each pocket is relatively small.

### Combining Shim Pockets

It is possible to build up a highly accurate model of combined pockets within the shim tubes. Neighboring trays can be combined by building up complex cross sections of sensitivity filaments, see FIGS. 3A and 3B. Once the cross section of the pocket has been constructed, the structure can be considered to be a single variable.

As illustrated in FIG. 3B, it is possible to reduce the number of calculations, yet still achieve a satisfactory calculated shim distribution by combining calculations for two, or more, adjacent shim tubes. A single calculation may be applied to corresponding filaments in each tube.

The combined cross section pockets can be initially optimized to produce a gross solution. Discarding the empty areas of the shim set and progressively refining to the remaining pockets will converge on a solution.

Optimization of shimming according to the present invention should include variation of the following features in highly discretized shim sets:
axial extent of cylindrical shims,
radial components of the shim magnetization vector.

The invention accordingly provides a passive shimming arrangement for magnets such as those used in imaging systems such as superconducting electromagnets or permanent magnets, for nuclear magnetic resonance or magnetic resonance imaging systems. The invention offers increased gradient coil strength; increased filling factor with shimming material of the space set aside for shimming, typically within the gradient coil; better thermal stability of the shims; and the possibility of improved automated shim loading, as compared to existing passive shim arrangements.

Although modifications and changes may be suggested by those skilled in the art, it is the intention of the inventors to embody within the patent warranted heron all changes and modifications as reasonably and properly come within the scope of their contribution to the art.

We claims as our invention:

1. A cylindrical magnet system for a magnetic resonance imaging comprising:
a cylindrical magnet having a bore extending therethrough and a longitudinal axis extending through said bore;
a gradient coil assembly located within said bore of said cylindrical magnet; and
an arrangement for passive shimming of the cylindrical magnet system comprising a plurality of tubes formed in said gradient coil assembly oriented parallel to said axis, and a plurality of planar pieces of shim material stacked in said tubes respectively in radial planes that are each perpendicular to and intersect and contain said longitudinal axis of said cylindrical magnet.

2. A magnet system as claimed in claim 1 wherein each tube has a cross-section in said radial planes perpendicular to said axis, said cross-section being complementary in shape to a shape of the respective pieces of shim material in said planes perpendicular to said axis.

3. A magnet system as claimed in claim 2 wherein said cross-section is circular and wherein said pieces of shim material are circular discs.

4. A magnet system as claimed in claim 1 comprising non-magnetic spacers stacked in said tubes together with said pieces of shim material, said spacers being selectively placed between respective pieces of shim material to support and retain and position said respective pieces of shim material and to produce a selected distribution of said pieces of shim material in said tubes.

5. A magnet system as claimed in claim 1 wherein each of said tubes has an open tube end, and comprising a tapered plug in each tube end, that retains the pieces of shim material within that tube.

6. A magnet system as claimed in claim 1 comprising a mounting element centrally located within each of said tubes, on which the pieces of shim material in that tube are mounted.

7. An arrangement as claimed in claim 6 wherein said mounting element is a conduit configured to carry a cooling medium therethrough.

8. A central magnet as claimed in claim 6 wherein each of said tubes has an open tube end, and comprising a tapered plug inserted in each tube and to centrally support said element in said tube and to hold said pieces of shim material within said tube.

9. A magnet system as claimed in claim 1 wherein each of said tubes has a tube axis, and wherein said tube axes are parallel to said axis of said cylindrical magnet.

10. A central magnet as claimed in claim 1 wherein said pieces of shim material have respectively different extents along said longitudinal axis.

11. A central magnet as claimed in claim 1 wherein each of said pieces of shim material has a same size and shape in said radial plane perpendicular to the longitudinal axis of the cylindrical magnet, said size and shape substantially corresponding to a cross-section of the respective tubes.

12. A magnet system as claimed in claim 1 wherein said pieces of shim material have respectively different sizes and shapes in said radial plane perpendicular to said axis of said cylindrical magnet.

13. A cylindrical magnet as claimed in claim 1 wherein said pieces of shim material are rounded, and wherein each tube of said gradient coil assembly has a rounded cross-section.

14. A cylindrical magnet as claimed in claim 1 wherein said pieces of shim material are circular, and wherein each tube of said gradient coil assembly has a circular cross-section.

15. A method for shimming a cylindrical magnet system comprising a cylindrical magnet having a bore therein and a longitudinal axis extending through said bore, and a gradient coil assembly located within said bore, said method comprising the steps of:
providing a plurality of tubes in said gradient coil assembly oriented in a direction parallel to said axis of said cylindrical magnet; and
stacking a plurality of planar pieces of shim material in said tubes to cause each planar piece of shim material to be in a radial plane perpendicular to and intersecting and containing said longitudinal axis of said cylindrical magnet.

16. A method as claimed in claim 15 comprising providing non-magnetic spacers in said tubes between respective pieces of shim material to position and distribute said pieces of shim material in said tubes.

17. A method as claimed in claim 15 comprising closing respective ends of said tubes with tapered plugs to retain said pieces of shim material within the respective tubes.

18. A method as claimed in claim 15 comprising providing a central mounting element in each of said tubes, and mounting the pieces of shim material in each tube on said central element.

19. A method as claimed in claim 18 comprising employing a pipe as said mounting element, and circulating a cooling medium through said pipe.
